(19) United States
(12) Patent Application Publication
(10) Pub. No.: US 2026/0371582 A1
(43) Pub. Date: Nov. 19, 2026

(54) Device with High-Density Memory Cells and Method of Manufacturing the Same

(71) Applicant: Taiwan Semiconductor Manufacturing Company, Ltd., Hsinchu (TW)

(72) Inventors: Ji-Kuan LEE, Hsinchu (TW); Chia-En HUANG, Hsinchu (TW); Yao-Jen YANG, Hsinchu (TW); Ting-Wei CHIANG, Hsinchu (TW)

(21) Appl. No.: 19/754,494

(22) Filed: Jul. 27, 2026

Related U.S. Application Data
(63) Continuation of application No. 18/815,976, filed on Aug. 27, 2024.

(51) Int. Cl. H10B 20/25

(52) U.S. Cl. CPC H10B 20/25

(57) ABSTRACT

A device includes a plurality of memory cells, each including a diffusion region and a plurality of transistors. The diffusion region is formed over a substrate. Each transistor is fabricated over the diffusion region and includes one or more source/drain contacts and one or more gate regions. The source/drain contacts and the gate regions are arranged along a first direction, each extend in a second direction transverse to the first direction, and overlap the diffusion region in a third direction transverse to the first and second directions. The gate regions of an adjacent pair of memory cells are free of a source/drain contact therebetween and have substantially the same contact poly pitch (CPP) as an adjacent pair of gate regions of a memory cell.

### CROSS-REFERENCE TO RELATED APPLICATION

The present application is a continuation application of U.S. patent application Ser. No. 18/815,976, filed Aug. 27, 2024, the contents of which are incorporated by reference herein in its entirety.

### BACKGROUND

Memory devices are responsible for storing and retrieving data. They come in various forms and can either be programmable or non-programmable. Programmable memory devices allow data to be written and rewritten multiple times, making them suitable for applications requiring frequent updates, such as RAM (random access memory) devices. Non-programmable memory devices, on the other hand, can only be written once, ensuring that the data remains unchanged, and are used in various applications where data needs to stay secure and cannot be tampered with, such as OTP (one-time programmable) memory devices. Regardless of their programmability, memory devices facilitate the reading of data stored therein, enabling electronic systems to access and utilize the information as needed.

### BRIEF DESCRIPTION OF THE DRAWINGS

Aspects of the present disclosure are best understood from the following detailed description when read with the accompanying figures:

FIG. 1 is a schematic block diagram illustrating an exemplary device in accordance with various embodiments of the present disclosure;

FIG. 2 is a schematic circuit diagram illustrating an exemplary memory cell of the device in accordance with various embodiments of the present disclosure;

FIG. 3 is a schematic layout diagram illustrating another exemplary memory cell in accordance with various embodiments of the present disclosure;

FIG. 4 is a schematic layout diagram illustrating another exemplary memory cell in accordance with various embodiments of the present disclosure;

FIG. 5 is a schematic layout diagram illustrating another exemplary memory cell in accordance with various embodiments of the present disclosure;

FIG. 6 is a schematic circuit diagram illustrating another exemplary memory cell in accordance with various embodiments of the present disclosure;

FIG. 7 is a schematic layout diagram illustrating another exemplary memory cell in accordance with various embodiments of the present disclosure;

FIG. 8 is a schematic layout diagram illustrating another exemplary memory cell 800 in accordance with various embodiments of the present disclosure;

FIG. 9 is a schematic circuit diagram illustrating another exemplary memory cell in accordance with various embodiments of the present disclosure;

FIG. 10 is a schematic layout diagram illustrating another exemplary memory cell in accordance with various embodiments of the present disclosure;

FIG. 11 is a schematic circuit diagram illustrating another exemplary memory cell in accordance with various embodiments of the present disclosure;

FIG. 12 is a schematic layout diagram illustrating another exemplary memory cell in accordance with various embodiments of the present disclosure; and

FIG. 13 is a flowchart of an exemplary method of manufacturing a device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underneath,” “below,” “lower,” “above,” “on,” “top,” “bottom” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

A memory device includes a plurality of memory cells, e.g., arranged in an array of rows and columns, facilitates the storing and reading of data stored in the memory cells, and can either be programmable or non-programmable. As noted above, programmable memory devices allow data to be written and rewritten multiple times, making them suitable for applications requiring frequent updates, such as RAM (random access memory) devices. In contrast, non-programmable memory devices, such as OTP (one-time programmable) memory devices, can only be written once, ensuring that the data remains unchanged. They are used in various applications where data needs to stay secure and cannot be tampered with. However, such memory cells may occupy a relatively large cell area of the memory device. For example, one or more gate regions, e.g., dummy gate regions or gate regions at the edges of or between diffusion regions, may be present between an adjacent pair of memory cells. This results in a low density for the memory cells, limiting the storage capacity of the memory device.

In certain examples described herein, systems and methods comprise a device that has relatively high-density memory cells. For example, instead of gate regions found in structures like PODE (poly over diffusion edge) and CPODE (continuous poly over diffusion edge), a cut region (e.g., a trench filled with a dielectric material) is formed between an adjacent pair of memory cells, between an adjacent pair of transistors of a memory cell, and/or between an adjacent pair of components of a transistor of a memory cell. This minimizes the CPP (contact poly pitch) therebetween. PODE and CPODE are types of schemes for scaling down CPP, with the CPODE having a smaller CPP than the PODE. As a result, the device area of the device of the present disclosure can be reduced by, e.g., 20% to 50%, compared to PODE and CPODE structures. In further detail, FIG. 1 is a schematic block diagram illustrating an exemplary device 100 in accordance with various embodiments of the present disclosure.

As illustrated in FIG. 1, the example device 100, e.g., a memory device, such as a RAM device or an OTP memory device, includes a plurality of memory cells 110, a plurality of word lines (WL0-WLn), and a plurality of bit lines (BL0-BLn). An OTP memory device is a type of memory device that permanently stores bits of data, which cannot be altered once written. For example, the OTP memory device includes a plurality of memory cells, each including an anti-fuse that is initially non-conductive, representing a logical ‘0’ (or ‘1’). The anti-fuse can be programmed to become conductive, e.g., by applying a high voltage signal thereto. This state represents a programmed bit, e.g., a logical ‘1’ (or ‘0’). Unlike a fuse, which is blown (i.e., becomes non-conductive, sometimes permanently) when programmed, an anti-fuse creates a conductive path, during programming.

The memory cells 110 may be arranged, e.g., in an array of rows and columns. The memory cells 110 in each row are connected to the respective word line (WL0-WLn). Similarly, the memory cells 110 in each column are connected to the respective bit line (BL0-BLn). The memory cell 110 stores a bit, either a logical ‘0’ or ‘1’, and undergoes, what is in some embodiments like OTP memory device, a permanent and irreversible change when written or programmed. For example, such an irreversible change occurs when a high voltage signal is applied to a corresponding word line (WL0-WLn), ensuring that the memory cell 110 cannot be reprogrammed (i.e., the bit stored therein cannot be overwritten).

In this exemplary embodiment, the memory cell 110 is implemented using an anti-fuse technology. As opposed to a fuse, which starts in a conductive state and becomes non-conductive when “blown” or programmed, an anti-fuse is initially an open-circuit, representing a logical ‘0’ (or ‘1’), and can be programmed to create a conductive path, representing a logical ‘1’ (or ‘0’), thereby making it permanently conductive and non-reprogrammable. In certain embodiments, instead of gate regions found in, e.g., PODE and CPODE structures, a cut region (e.g., a trench filled with a dielectric material) is formed between an adjacent pair of memory cells 110, between an adjacent pair of transistors of the memory cell 110, and/or between an adjacent pair of components of a transistor of the memory cell 110. This minimizes a CPP therebetween. This, in turn, results in a reduction of the device area of the device of the present disclosure by, e.g., 20% to 50%, compared to PODE and CPODE structures.

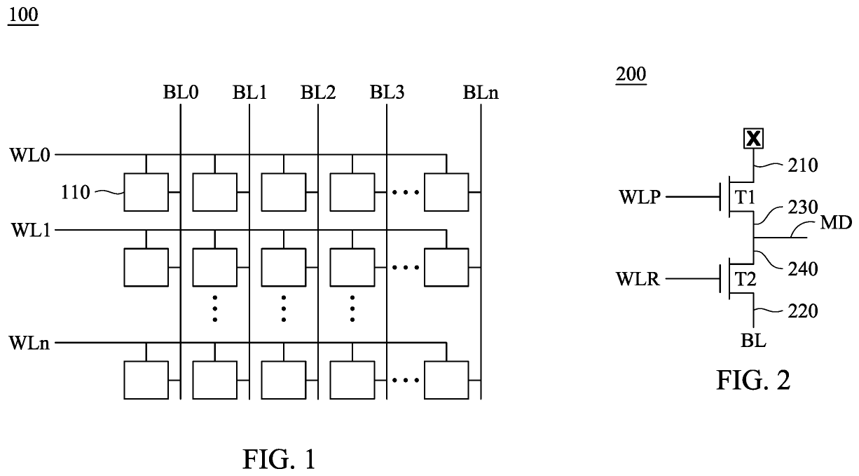

FIG. 2 is a schematic circuit diagram illustrating another exemplary memory cell 200 in accordance with various embodiments of the present disclosure. As illustrated in FIG. 2, the example memory cell 200, e.g., memory cell 110, is in the form of a two-transistor (2T) memory cell and includes an anti-fuse transistor (T1) and a select transistor (T2). In this exemplary embodiment, the transistor (T1, T2) is an n-type metal-oxide-semiconductor field-effect transistor (nMOSFET). In an alternative embodiment, at least one of the transistors (T1, T2) is a p-type metal-oxide-semiconductor field-effect transistor (pMOSFET).

The transistor (T1) has a floating source/drain terminal 210 that does not receive any signals, e.g., a voltage or ground signal. The transistor (T2) has a bit line (BL) source/drain terminal 220 connected to a bit line (BL) for sensing the bit stored in the memory cell 200 during a read operation on the memory cell 200. The second source/drain terminal 230 of the transistor (T1) and the second source/drain terminal 240 of the transistor (T2) are connected to each other and to a source/drain contact (MD). An MD (or metal layer) is a conductive material, e.g. tungsten (W), cobalt (Co), titanium (T1), other suitable metals, and alloys thereof, deposited over a source/drain region to serve as a conductive path.

The gate terminal of the transistor (T1) is connected to a first word line that receives a word line programming (WLP) signal for altering the state of the transistor (T1) during a write (or programming) operation on the memory cell 200. The gate terminal of the transistor (T2) is connected to a second word line that receives a word line read (WLR) signal for retrieving the bit stored in the memory cell 200 during a read operation on the memory cell 200.

From the above description, the memory cell 200 uses a combination of two transistors (T1, T2) to permanently store a bit therein by altering the state of the transistor (T1). For example, prior to programming, the gate dielectric of the transistor (T1) is intact, i.e., there is no conductive path through the transistor (T1). The absence of a conductive path indicates that a logical ‘0’ (or ‘1’) is stored in the memory cell 200. During a write or programming operation on the memory cell 200, a word line programming (WLP) signal, e.g., a high voltage signal, is applied to the gate terminal of the transistor (T1). This may induce a dielectric breakdown of the gate dielectric of the transistor (T1), forming a permanent conductive path (a short circuit) in the transistor (T1). This permanent conductive path represents a logical ‘1’(or ‘0’) is stored in the transistor (T1).

Thereafter, when it is desired to perform a read operation on the memory cell 200, the bit line (BL) is pre-charged to a predetermined voltage level. Subsequently, a word line read (WLR) signal is applied to the gate terminal of the transistor (T2), activating the transistor (T2). This connects the bit line (BL) to the transistor (T1) through the transistor (T2). If the transistor (T1) is programmed, a current flows through the transistor (T1, T2) and a sense amplifier connected to the bit line (BL) interprets the bit stored in the transistor (T1) as a logical ‘1’ (or ‘0’). Conversely, if the transistor (T1) is unprogrammed, the transistor (T1) remains non-conductive and substantially no current flows through the transistor (T1). At this state, the sense amplifier interprets the bit stored in the memory cell 200 as a logical ‘0’(or ‘1’).

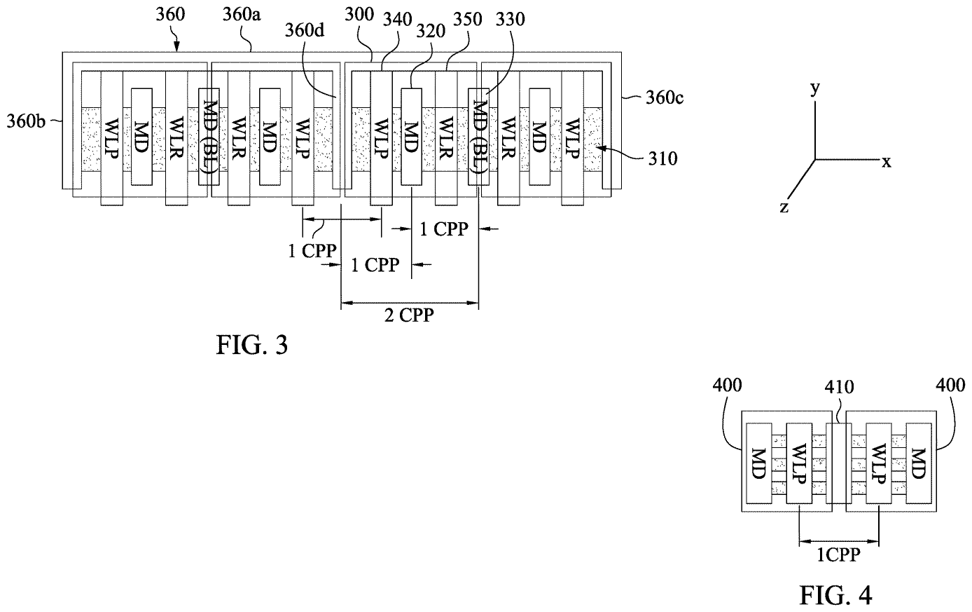

FIG. 3 is a schematic layout diagram illustrating another exemplary memory cell 300, e.g., memory cell 110, in accordance with various embodiments of the present disclosure. As illustrated in FIG. 3, the example memory cells (only one of the memory cells is labeled as 300 in FIG. 3) are arranged along a first direction (x). Because the memory cells are similar in structure, only one will be described. The memory cell 300 includes a diffusion region 310, first and second source/drain contacts 320, 330, first and second gate regions 340, 350, and a cut region 360. The diffusion region 310, e.g., active region or region at which transistors are fabricated, is formed over a substrate and extends in the first direction (x).

The cut region 360 surrounds the memory cells 300 and includes a plurality of cut region portions 360a-360d. For example, the cut region portion 360a extends in the first direction (x). Each cut region portions 360b, 360c extends in a second direction (y) transverse to the first direction (x), interconnected by the cut region portion 360a, and abuts (or defines) a respective edge of the diffusion region 310. The cut region portion 360d cuts (or divides) the diffusion region 310 into halves and defines the edge of each half. The cut region portions 360a, 360d cooperatively form a generally T shape. The cut region 360 is a trench formed in the substrate and filled with a dielectric material. Examples of dielectric materials for the cut region 360 include SiO₂, SiN, HfO₂, TaO₂, TiO2, and other suitable dielectric materials.

The source/drain contacts 320, 330, e.g., MD layers, and the gate regions 340, 350, e.g., polysilicon lines or metal gates, are arranged along the length of the diffusion region 310, each extend in the second direction (y), and overlap the diffusion region 310 in a third direction (z) transverse to the first and second directions (x, y). The source/drain contact 320 is connected to the source/drain region 230 of the transistor (T1) and the source/drain region 240 of the transistor (T2). The source/drain contact 330 is connected to the source/drain region 220 of the transistor (T2) and the bit line (BL).

The gate region 340, 350 corresponds to the gate terminal of the transistor (T1, T2). In some embodiments, the gate region 340, 350 includes a polysilicon. In other embodiments, the gate region 340, 350 includes TiN, W, Ta, Al, Mo, Co, other suitable metal gate materials, or an alloy thereof. In this exemplary embodiment, the memory cell 300 is a two-contact poly pitch (2 CPP) memory cell. CPP refers to the distance between adjacent features, such as MD contacts 320, 330 and polysilicon lines 340, 350. As can be seen from FIG. 3, the CPP between the cut region portion 360d and the source/drain contact 320 is 1 unit (e.g., 1 nm) and the CPP between the source/drain contacts 320, 330 is also 1 unit.

From the above description, a cut region portion 360d is disposed between an adjacent pair of the memory cells, decreasing a CPP therebetween. This decrease in CPP results in a relatively smaller device area for the device 100 of the present disclosure. For example, FIG. 4 is a schematic layout diagram illustrating another exemplary memory cell 400, e.g., memory cell 110, in accordance with various embodiments of the present disclosure. As illustrated in FIG. 4, instead of gate regions and/or MD layers found in structures like PODE and CPODE, a cut region 410 is formed between an adjacent pair of memory cells 400. This minimizes the CPP between an adjacent pair of memory cells 400 from greater than 1 unit (e.g., 5 units) to less than 5 units (e.g., 1 unit). This, in turn, results in the reduction of the device area of the device 100 of the present disclosure by up to 20% to 50% compared to PODE and CPODE structures.

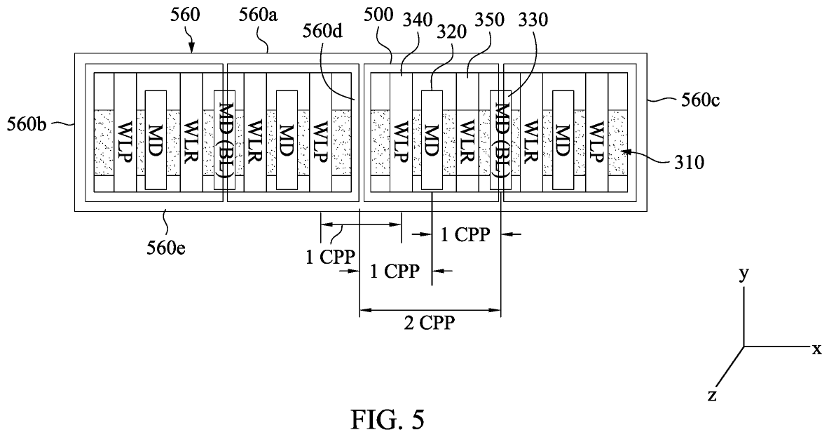

FIG. 5 is a schematic layout diagram illustrating another exemplary memory cell 500, e.g., memory cell 110, in accordance with various embodiments of the present disclosure. As illustrated in FIG. 5, the example memory cells (only one of the memory cells is labeled as 500 in FIG. 5) of this embodiment differs from the previous embodiments in that the cut region 560 surrounds (i.e., is disposed at left, right, top, and bottom boundaries of) the memory cells 500 and includes cut region portions 560a-560e. The cut region portions 560a, 560e each extend in the first direction (x) and are opposite to each other in the second direction (y). Each cut region portion 560b, 560c extends in the second direction (y), interconnects the cut region portions 560a, 560e, and abuts (or defines) a respective edge of the diffusion region 310. The cut region portion 560d cuts (or divides) the diffusion region 310 into halves, defines the edge of each half, and cooperates with the cut region portion 560a to form a generally T shape. The cut region 560 is a trench formed in the substrate and filled with a dielectric material. Examples of dielectric materials for the cut region 560 include SiO₂, SiN, HfO₂, TaO₂, TiO₂, and other suitable dielectric materials.

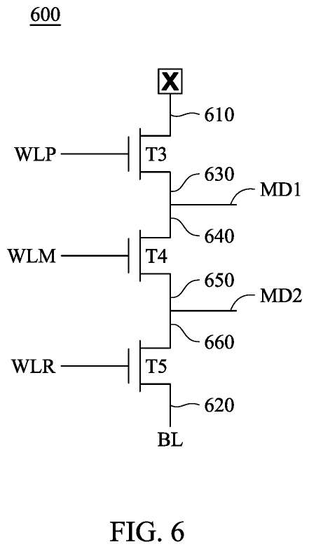

Although the memory cell 200-500 is exemplified as a 2T memory cell, it should be understood that, after reading this disclosure, the number of transistors of memory cell 200-500 may be increased or decrease as desired. For example, FIG. 6 is a schematic circuit diagram illustrating another exemplary memory cell 600 in accordance with various embodiments of the present disclosure. As illustrated in FIG. 6, the example memory cell 600, e.g., memory cell 110, is in the form of a three-transistor (3T) memory cell and includes an anti-fuse transistor (T3), a pass transistor (T4), and a select transistor (T5). In this exemplary embodiment, the transistor (T3-T5) is an nMOSFET. In an alternative embodiment, at least one of the transistors (T3-T5) is a pMOSFET.

The transistor (T3) has a floating source/drain terminal 610 that does not receive any signals, e.g., a voltage or ground signal. The transistor (T5) has a bit line (BL) source/drain terminal 620 connected to a bit line (BL) for sensing the bit stored in the memory cell 600 during a read operation on the memory cell 600. The second source/drain terminal 630 of the transistor (T3) and the first source/drain terminal 640 of the transistor (T4) are connected to each other and to a first source/drain contact (MD1). The second source/drain terminal 650 of the transistor (T4) and the second source/drain terminal 660 of the transistor (T5) are connected to each other and to a second source/drain contact (MD2).

The gate terminal of the transistor (T3) is connected to a first word line that receives a first word line programming (WLP) signal for altering the state of the transistor (T3) during a write (or programming) operation on the memory cell 600. The gate terminal of the transistor (T4) is connected to a second word line and receives a word line activating (WLM) signal for connecting the transistor (T5) to the transistor (T4) during programming and/or read operation on the memory cell 600. The gate terminal of the transistor (T5) is connected to a third word line that receives a word line read (WLR) signal for retrieving the bit stored in the memory cell 300 during a read operation on the memory cell 600.

From the above description, the memory cell 600 involves the use of three transistors (T3-T5) to permanently store a bit therein by altering the state of the transistor (T3). For example, prior to programming, the gate dielectric of the transistor (T3, T4) is intact, i.e., there is no conductive path through the transistor (T3, T4). The absence of a conductive path indicates that a logical ‘0’ (or ‘1’) is stored in the memory cell 600. During a write or programming operation on the memory cell 600, a word line programming (WLP) signal, e.g., a high voltage signal, is applied to the gate terminal of the transistor (T3). This may induce a dielectric breakdown of the gate dielectric of the transistor (T3, T4), forming a permanent conductive path (a short circuit) in the transistor (T3). This permanent conductive path represents a logical ‘1’(or ‘0’) is stored in the transistor (T3).

Thereafter, when it is desired to perform a read operation on the memory cell 600, the bit line (BL) is pre-charged to a predetermined voltage level. Subsequently, a word line reading (WLR) signal is applied to the gate terminal of the transistor (T5), activating the transistor (T5). At substantially the same time, the transistor (T5) is turned on by a word line activating (WLM) signal at the gate terminal thereof. This connects the bit line (BL) to the transistor (T3) through the transistors (T4, T5). If the transistor (T3) is programmed, a current flows through the transistor (T3-T5) and a sense amplifier connected to the bit line (BL) interprets the bit stored in the transistor (T3) as a logical ‘1’ (or ‘0’). Conversely, if the transistor (T3, T4) is unprogrammed, the transistor (T3) remains non-conductive and substantially no current flows through the transistor (T3). At this state, the sense amplifier interprets the bit stored in the memory cell 600 as a logical ‘0’(or ‘1’).

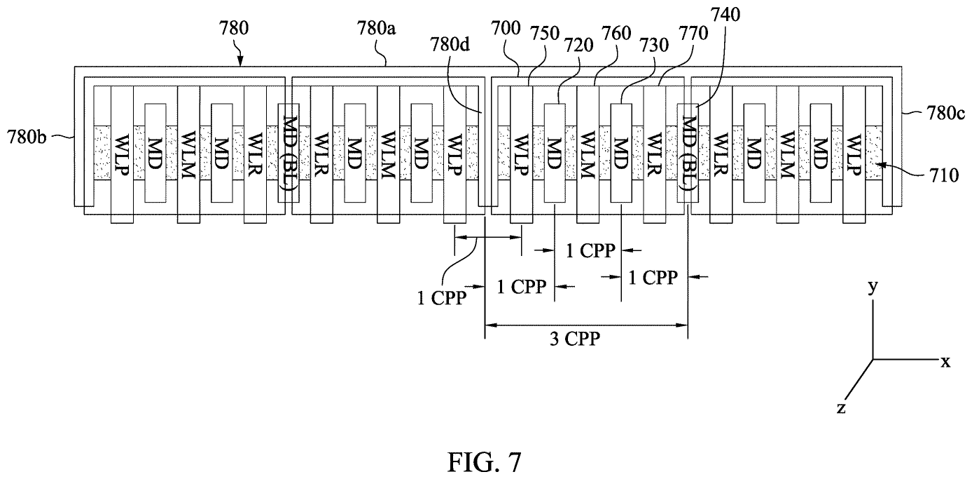

FIG. 7 is a schematic layout diagram illustrating another exemplary memory cell 700 in accordance with various embodiments of the present disclosure. As illustrated in FIG. 7, the example memory cells (only one of the memory cells is labeled as 700 in FIG. 7) are arranged along the first direction (x). Because the memory cells are similar in structure, only one will be described. The memory cell 700 includes a diffusion region 710, first to third source/drain contacts 720-740, first to second gate regions 750-760, and a cut region 780. The diffusion region 710, e.g., an OD region, is formed over a substrate and extends in the first direction (x).

The cut region 780 surrounds the memory cells and includes a plurality of cut region portions 780a-780d. For example, the cut region portion 780a extends in the first direction (x). Each cut region portions 780b, 780c extends in the second direction (y), interconnected by the cut region portion 780a, and abuts (or defines) a respective edge of the diffusion region 710. The cut region portion 780d cuts (or divides) the diffusion region 710 into halves and defines the edge of each half. The cut region portions 780a, 780d cooperatively form a generally T shape. The cut region 780 is a trench formed in the substrate and filled with a dielectric material. Examples of such dielectric materials for the cut region 780 include SiO₂, SiN, HfO₂, TaO₂, TiO₂, and other suitable dielectric materials.

The source/drain contacts 720-740, e.g., MD layers, and the gate regions 750-770, e.g., polysilicon lines or metal gates, of the memory cell 700 are arranged along the length of the diffusion region 710, each extend in the second direction (y), and overlap the diffusion region 710 in the third direction (z). The source/drain contact 720 is connected to the source/drain region 630 of the transistor (T3) and the source/drain region 640 of the transistor (T4). The source/drain contact 730 is connected to the source/drain region 650 of the transistor (T4) and the source/drain region 660 of the transistor (T5). The source/drain contact 740 is connected to the source/drain region 620 of the transistor (T5) and the bit line (BL). In certain embodiments, the source/drain contact 720-740 is made of a conductive material such as copper, aluminum, tungsten, titanium, other suitable conductive materials, or an alloy thereof.

The gate region 750-770 corresponds to the gate terminal of the transistor (T3-T5). In some embodiments, the gate region 750-770 includes a polysilicon. In other embodiments, the gate region 750-770 includes TiN, W, Ta, Al, Mo, Co, other suitable metal gate materials, or an alloy thereof. In this exemplary embodiment, the memory cell 700 is a three-contact poly pitch (3 CPP) memory cell. CPP refers to the distance between adjacent features, such as MD contacts 720-740 and polysilicon lines 750-770. As can be seen from FIG. 7, the CPP between the cut region portion 780d and the source/drain contact 720 is 1 unit (e.g., 1 nm). Similarly, the CPP between the source/drain contacts 720, 730 is 1 unit and the CPP between the source/drain contacts 730, 740 is also 1 unit.

From the above description, a cut region portion 780d is between an adjacent pair of the memory cells 700, decreasing a CPP therebetween. This decrease in CPP results in a relatively smaller device area for the device 100 of the present disclosure. For example, as illustrated in FIG. 7, instead of gate regions and/or MD layers found in structures like PODE and CPODE, a cut region 780d is formed between an adjacent pair of memory cells. This minimizes the CPP between an adjacent pair of memory cells of the device 100 from greater than 1 unit (e.g., 5 units) to less than 5 units (e.g., 1 unit). This, in turn, results in the reduction of the device area of the device 100 of the present disclosure by up to 20% to 50% compared to PODE and CPODE structures.

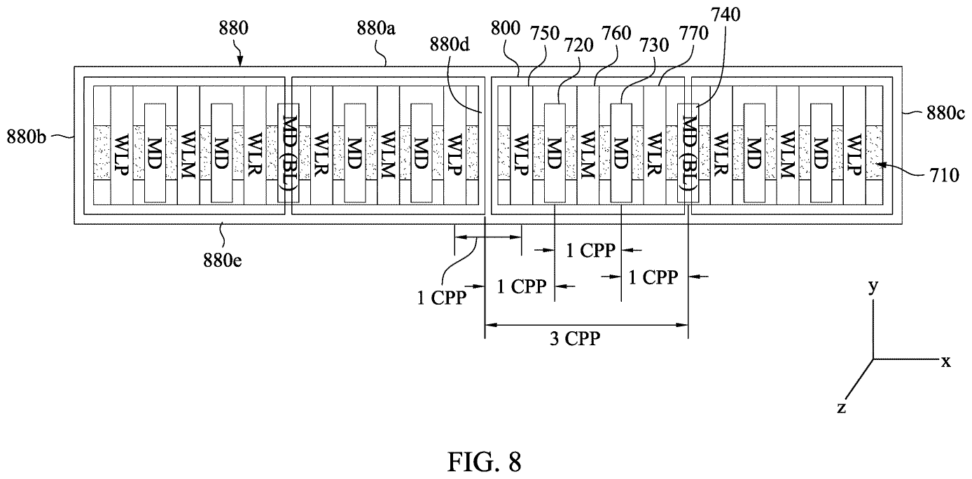

FIG. 8 is a schematic layout diagram illustrating another exemplary memory cell 800, e.g., memory cell 110, in accordance with various embodiments of the present disclosure. As illustrated in FIG. 8, the example memory cells (only one of the memory cells is labeled as 800 in FIG. 8) in this embodiment differs from the previous embodiments in that the cut region 880 surrounds (i.e., is disposed at left, right, top, and bottom boundaries of) the memory cells 800 and includes cut region portions 880a-880e. The cut region portions 880a, 880e each extend in the first direction (x) and are opposite to each other in the second direction (y). Each cut region portion 880b, 880c extends in the second direction (y), interconnects the cut region portions 880a, 880e, and abuts (or defines) a respective edge of the diffusion region 710. The cut region portion 880d cuts (or divides) the diffusion region 710 into halves, defines the edge of each half, and cooperates with the cut region portion 880a to form a generally T shape. The cut region 880 is a trench formed in the substrate and filled with a dielectric material. Examples of dielectric materials for the cut region 880 include SiO₂, SiN, HfO₂, TaO₂, TiO₂, and other suitable dielectric materials.

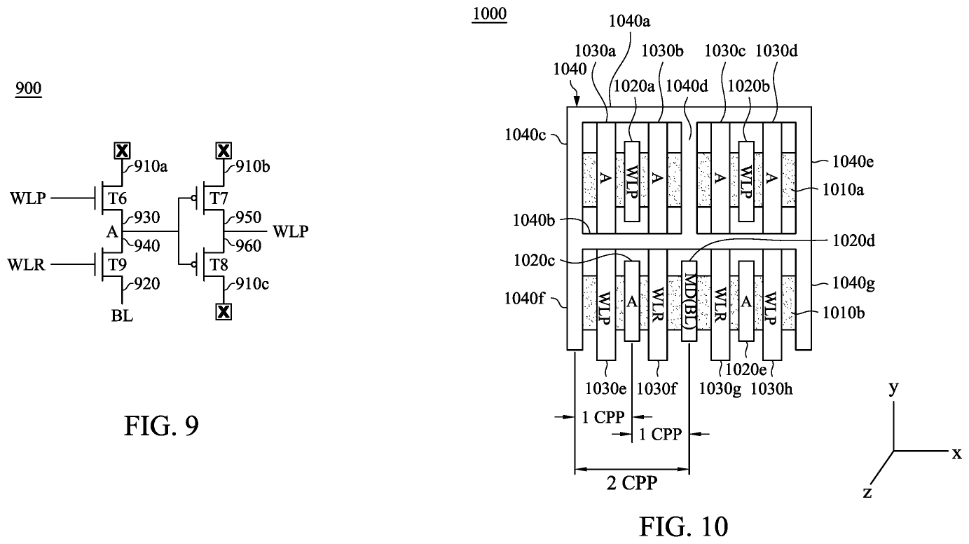

FIG. 9 is a schematic circuit diagram illustrating another exemplary memory cell 900 in accordance with various embodiments of the present disclosure. As illustrated in FIG. 9, the example memory cell 900, e.g., memory cell 110, is in the form of a four-transistor (4T) memory cell and includes first to third anti-fuse transistors (T6-T8) and a select transistor (T9). In this exemplary embodiment, the transistor (T6, T9) is an nMOSFET, whereas the transistor (T7, T8) is a pMOSFET. In an alternative embodiment, at least one of the transistors (T6, T9) is a pMOSFET and at least one of the transistors (T7, T8) is an nMOSFET.

The transistor (T6-T8) has a floating source/drain terminal 910a, 910b, 910c that does not receive any signals, e.g., a voltage or ground signal. The transistor (T9) has a bit line (BL) source/drain terminal 920 connected to a bit line (BL) for sensing the bit stored in the memory cell 900 during a read operation on the memory cell 900. The second source/drain terminal 930 of the transistor (T6) and the second source/drain terminal 940 of the transistor (T9) are connected to each other and to a source/drain contact (A).

The gate terminal of the transistor (T6) is connected to a first word line that receives a word line programming (WLP) signal for altering the state of the transistor (T6) during a write (or programming) operation on the memory cell 900. The gate terminal of the transistor (T9) is connected to a second word line that receives a word line read (WLR) signal for retrieving the bit stored in the memory cell 900 during a read operation on the memory cell 900. The second source/drain terminal 950 of the transistor (T7) and the second source/drain terminal 960 of the transistor (T8) are connected to each other and to the gate terminal of the transistor (T6). The gate terminal of the transistor (T7) and the gate terminal of the transistor (T8) are connected to each other and to the source/drain contact (A).

From the above description, the memory cell 900 includes four transistors (T6-T9) to permanently store a bit therein by altering the state of at least one of the transistors (T6-T8). For example, prior to programming, the gate dielectric of the transistor (T6-T8) is intact, i.e., there is no conductive path through the transistor (T6-T8). The absence of a conductive path indicates that a logical ‘0’ (or ‘1’) is stored in the memory cell 900. During a write or programming operation on the memory cell 900, a word line programming (WLP) signal, e.g., a high voltage signal, is applied to the gate terminal of the transistor (T6) and the source/drain terminal 950, 960 of the transistor (T7, T8). This may induce a dielectric breakdown of the gate dielectric of at least one of the transistors (T6-T8), forming a permanent conductive path (a short circuit) in the at least one of the transistor (T6-T8). This permanent conductive path represents a logical ‘1’ (or ‘0’) is stored in the transistor (T6-T8).

Thereafter, when it is desired to perform a read operation on the memory cell 900, the bit line (BL) is pre-charged to a predetermined voltage level. Subsequently, a word line reading (WLR) signal is applied to the gate terminal of the transistor (T9), activating the transistor (T9). This connects the bit line (BL) to the transistor (T6-T8) through the transistor (T9). If the transistor (T6-T8) is programmed, a current flows through the transistor (T6-T9) and a sense amplifier connected to the bit line (BL) interprets the bit stored in the transistor (T6-T8) as a logical ‘1’ (or ‘0’). Conversely, if the transistor (T6-T8) is unprogrammed, the transistor (T6-T8) remains non-conductive and substantially no current flows through the transistor (T6-T8). At this state, the sense amplifier interprets the bit stored in the memory cell 900 as a logical ‘0’ (or ‘1’).

FIG. 10 is a schematic layout diagram illustrating another exemplary memory cell 1000 in accordance with various embodiments of the present disclosure. As illustrated in FIG. 10, the example memory cell 1000 includes first and second diffusion regions 1010a, 1010b, first-fifth source/drain contacts 1020a-1020e, first-eighth gate regions 1030a-1030h, and a cut region 1040. The diffusion regions 1010a, 1010b, e.g., OD regions, are formed over a substrate, each extend in the first direction (x), and are spaced apart from each other in the second direction (y).

The cut region 1040 includes a plurality of cut region portions 1040a-1040g. For example, the cut region portions 1040a, 1040b each extend in the first direction (x) and are spaced apart from each other in the second direction (y). Each cut region portion 1040c,1040e extends in the second direction (y), interconnects the cut region portions 1040a, 1040b, and abuts (or defines) a respective edge of the diffusion region 1010a. The cut region portion 1040d cuts (or divides) the diffusion region 1010a into halves, defines the edge of each half, and cooperates with the cut region portion 1040a to form a generally T shape. In this exemplary embodiment, the cut region portions 1040a, 1040b, 1040c, and 1040e surround the transistors (T7, T8). In addition, the cut region portions 1040a-1040d are at the boundary of one of the transistors (T7, T8). Moreover, the cut region portions 1040a, 1040b, 1040d, 1040e are at the boundary of the other of the transistors (T7, T8).

Each cut region portion 1040f, 1040g extends in the second direction (y), interconnected by the cut region portion 1040b, and abuts (or defines) a respective edge of the diffusion region 1010b. In this exemplary embodiment, the cut region portions 1040b, 1040f, and 1040g surround the transistors (T6, T9). The cut region 1040 is a trench formed in the substrate and filled with a dielectric material. Examples of dielectric materials for the cut region 1040 include SiO₂, SiN, HfO₂, TaO₂, TiO₂, and other suitable dielectric materials.

The source/drain contacts 1020a, 1020b, e.g., MD layers, and the gate regions 1030a-1030d, e.g., polysilicon lines or metal gates, are arranged along the length of the diffusion region 1010a, each extend in the second direction (y), and overlap the diffusion region 1010a in the third direction (z). The source/drain contacts 1020c-1020e, e.g., MD layers, and the gate regions 1030e-1030h, e.g., polysilicon lines or metal gates, are arranged along the length of the diffusion region 1010b, each extend in the second direction (y), and overlap the diffusion region 1010b in the third direction (z). The source/drain contact 1020a, 1020b is connected to the source/drain region 950, 960 of the transistor (T7, T8) and to the gate terminal of the transistor (T6).

The source/drain contact 1020c, 1020e is connected to the source/drain region 930, 940 of the transistor (T6, T9) and to the gate terminal of the transistor (T7, T8). The source/drain contact 1020d is connected to the source/drain terminal 920 of the transistor (T9) and the bit line (BL). In certain embodiments, the source/drain contact 1020a-1020e is made of a conductive material such as copper, aluminum, tungsten, titanium, other suitable conductive materials, or an alloy thereof.

The gate region 1030a-1030d corresponds to the gate terminal of the transistor (T7, T8). The gate region 1030e, 1030h corresponds to the gate terminal of the transistor (T6). The gate region 1030f, 1030g corresponds to the gate terminal of the transistor (T9). In some embodiments, the gate region 1030a-1030h includes a polysilicon. In other embodiments, the gate region 1030a-1030h includes TiN, W, Ta, Al, Mo, Co, other suitable metal gate materials, or an alloy thereof.

In this exemplary embodiment, the memory cell 1000 is a 2 CPP memory cell. CPP refers to the distance between adjacent features, such as MD contacts 1020a-1020e and polysilicon lines 1030a, 1030f. As can be seen from FIG. 10, the CPP between the cut region portion 1040f and the source/drain contact 1020 c is 1 unit (e.g., 1 nm) and the CPP between the source/drain contacts 1020 c, 1020d is also 1 unit.

From the above description, a cut region 1040 is between an adjacent pair of memory cells, decreasing a CPP therebetween. This decrease in CPP results in a relatively smaller device area for the device 100 of the present disclosure. For example, at illustrated in FIG. 10, instead of gate regions and/or MD layers found in structures like PODE and CPODE, cut regions 1040a-1040g are formed between an adjacent pair of memory cells 1000. This minimizes the CPP between an adjacent pair of memory cells of the device 100 from greater than 1 unit (e.g., 5 units) to less than 5 units (e.g., 1 unit). This, in turn, results in the reduction of the device area of the device 100 of the present disclosure by up to between 20% and 50% compared to PODE and CPODE structures.

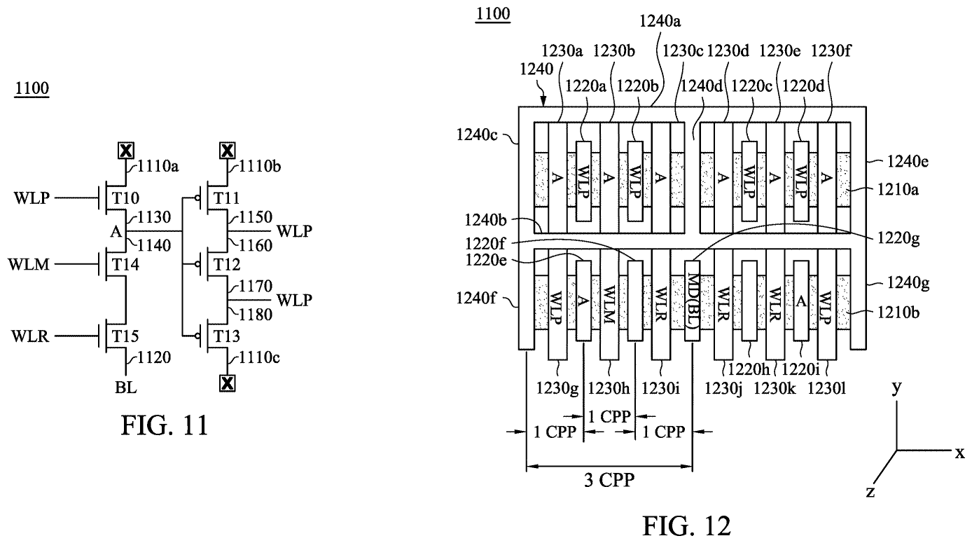

FIG. 11 is a schematic circuit diagram illustrating another exemplary memory cell 1100 in accordance with various embodiments of the present disclosure. As illustrated in FIG. 11, the example memory cell 1100 is in the form of a six-transistor (6T) memory cell and includes first to fourth anti-fuse transistors (T10-T13), a pass transistor (T14), and a select transistor (T15). In this exemplary embodiment, the transistor (T10, T14, T15) is an nMOSFET, whereas the transistor (T11-T13) is a pMOSFET. In an alternative embodiment, at least one of the transistors (T10, T14, T15) is a pMOSFET and at least one of the transistors (T11-T13) is an nMOSFET.

The transistor (T10, T11, T13) has a floating source/drain terminal 1110a, 1110b, 1110c that does not receive any signals, e.g., a voltage or ground signal. The transistor (T15) has a bit line (BL) source/drain terminal 1120 connected to a bit line (BL) for sensing the bit stored in the memory cell 1100 during a read operation on the memory cell 1100. The second source/drain terminal 1130 of the transistor (T10) and the first source/drain terminal 1140 of the transistor (T14) are connected to each other and to a source/drain contact (A). The second source/drain terminal of the transistor (T14) and the second source/drain terminal of the transistor (T15) are connected to each other.

The gate terminal of the transistor (T10) is connected to a first word line that receives a word line programming (WLP) signal for altering the state of the transistor (T10) during a write (or programming) operation on the memory cell 1100. The gate terminal of the transistor (T14) is connected to a second word line and receives a word line activating (WLM) signal for connecting the transistor (T15) to the transistor (T10) during a programming and/or read operation on the memory cell 1100. The gate terminal of the transistor (T15) is connected to a third word line that receives a word line read (WLR) signal for retrieving the bit stored in the memory cell 1100 during a read operation on the memory cell 1100.

The second source/drain terminal 1150 of the transistor (T11) and the first source/drain terminal 1160 of the transistor (T12) are connected to each other and to the gate terminal of the transistor (T10). The second source/drain terminal 1170 of the transistor (T12) and the second source/drain terminal 1180 of the transistor (T13) are connected to each other and to the gate terminal of the transistor (T10). The gate terminal of the transistor (T12), the gate terminal of the transistor (T13), and the gate terminal of the transistor (T4) are connected to each other and to the source/drain contact (A).

From the above description, the memory cell 1100 is implemented with six transistors (T10-T15) to permanently store a bit therein by altering the state of at least one of the transistors (T10-T13). For example, prior to programming, the gate dielectric of the transistor (T10-T13) is intact, i.e., there is no conductive path through the transistor (T10-T13). The absence of a conductive path indicates that a logical ‘0’ (or ‘1’) is stored in the memory cell 1100. During a write or programming operation on the memory cell 1100, a word line programming (WLP) signal, e.g., a high voltage signal, is applied to the gate terminal of the transistor (T10) and the source/drain terminal 1150-1180 of the transistor (T12-T14). This may induce a dielectric breakdown of the gate dielectric of at least one of the transistors (T10-T13), forming a permanent conductive path (a short circuit) in the at least one of the transistors (T10-T13). This permanent conductive path represents a logical ‘1’ (or ‘0’) is stored in the transistor (T1-T14).

Thereafter, when it is desired to perform a read operation on the memory cell 1100, the bit line (BL) is pre-charged to a predetermined voltage level. Subsequently, a word line reading (WLR) signal is applied to the gate terminal of the transistor (T15), activating the transistor (T15). At substantially the same time, the transistor (T14) is turned on by a word line activating (WLM) signal at the gate terminal thereof. This connects the bit line (BL) to the transistor (T10-T13) through the transistor (T14). If the transistor (T10-T13) is programmed, a current flows through the transistor (T10-T15) and a sense amplifier connected to the bit line (BL) interprets the bit stored in the transistor (T10-T13) as a logical ‘1’ (or ‘0’). Conversely, if the transistor (T10-T13) is unprogrammed, the transistor (T10-T13) remains non-conductive and substantially no current flows through the transistor (T10-T13). At this state, the sense amplifier interprets the bit stored in the memory cell 1100 as a logical ‘0’(or ‘1’).

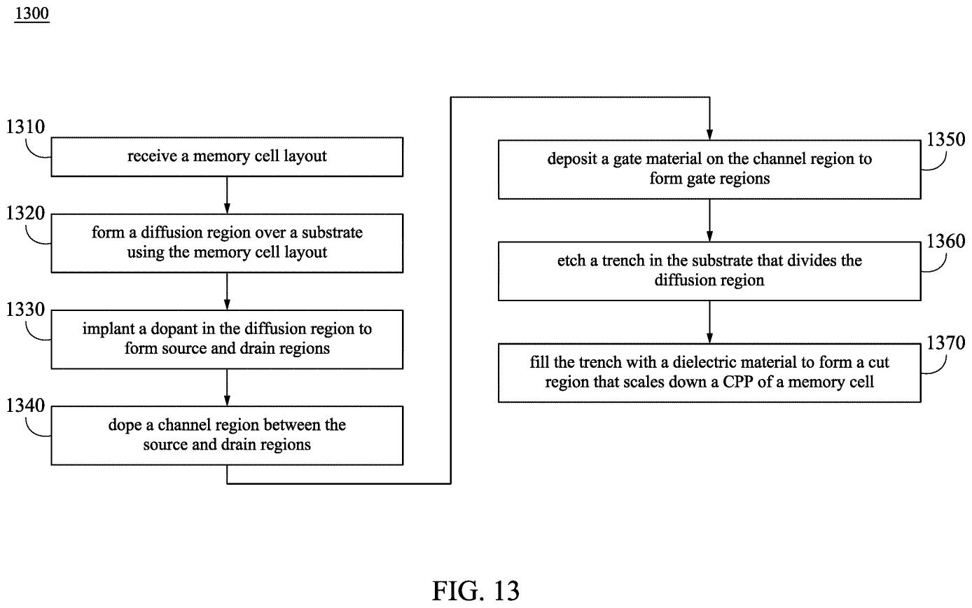

FIG. 12 is a schematic layout diagram illustrating another exemplary memory cell 1200 in accordance with various embodiments of the present disclosure. As illustrated in FIG. 12, the example memory cell 1200 includes first and second diffusion regions 1210a, 1210b, first-ninth source/drain contacts 1220a-1220i, first-twelfth gate regions 1230a-1230l, and a cut region 1240. The diffusion regions 1210a, 1210b, e.g., OD regions, are formed over a substrate, each extend in the first direction (x), and are spaced apart from each other in the second direction (y).

The cut region 1240 includes a plurality of cut region portions 1240a-1240g. For example, the cut region portions 1240a, 1240b each extend in the first direction (x) and are spaced apart from each other in the second direction (y). Each cut region portion 1240c, 1240e extends in the second direction (y), interconnects the cut region portions 1240a, 1240b, and abuts (or defines) a respective edge of the diffusion region 1210a. The cut region portion 1240d cuts (or divides) the diffusion region 1210a into halves, defines the edge of each half, and cooperates with the cut region portion 1240a to form a generally T shape. In this exemplary embodiment, the cut region portions 1240a, 1240b, 1240c and 1240e surround the transistors (T11-T13). In addition, the cut region portions 1240a-1240d are at the boundary of the transistors (T11-T13). Moreover, the cut region portions 1240a, 1240b, 1240d, 1240e are at the boundary of the transistors (T11-T13).

Each cut region portions 1240f, 1240g extends in the second direction (y), interconnected by the cut region portion 1240b, and abuts (or defines) a respective edge of the diffusion region 1210b. In this exemplary embodiment, the cut region portions 1240b, 1240f, and 1240g surround the transistors (T10, T14, T15). The cut region 1240 is a trench formed in the substrate and filled with a dielectric material. Examples of dielectric materials for the cut region 1040 include SiO₂, SiN, HfO₂, TaO₂, TiO₂, and other suitable dielectric materials.

The source/drain contacts 1220a-1220d, e.g., MD layers, and the gate regions 1230a-1230f, e.g., polysilicon lines or metal gates, are arranged along the length of the diffusion region 1210a, each extend in the second direction (y), and overlap the diffusion region 1210a in the third direction (z). The source/drain contacts 1220e-1220i, e.g., MD layers, and the gate regions 1230g-1230l, e.g., polysilicon lines or metal gates, are arranged along the length of the diffusion region 1210b, each extend in the second direction (y), and overlap the diffusion region 1210b in the third direction (z). The source/drain contact 1220a-1220d is connected to the source/drain region 1150, 1160, 1170, 1180 of the transistor (T11-T13) and to the gate terminal of the transistor (T10).

The source/drain contact 1220e, 1220i is connected to the source/drain region 1130, 1140 of the transistor (T10, T14) and to the gate terminal of the transistor (T11-T13). The source/drain contact 1220f, 1220h is connected to the source/drain region of the transistor (T14, T15). The source/drain contact 1220g is connected to the source/drain terminal 1120 of the transistor (T15) and the bit line (BL). In certain embodiments, the source/drain contact 1220a-1220i is made of a conductive material such as copper, aluminum, tungsten, titanium, other suitable conductive materials, or an alloy thereof.

The gate region 1230a-1230f corresponds to the gate terminal of the transistor (T11-T13). The gate region 1230g, 1230l corresponds to the gate terminal of the transistor (T10). The gate region 1230h corresponds to the gate terminal of the transistor (T14). The gate region 1230i-1230k corresponds to the gate terminal of the transistor (T15). In some embodiments, the gate region 1230a-1230l includes a polysilicon. In other embodiments, the gate region 1230a-1230l includes TiN, W, Ta, Al, Mo, Co, other suitable metal gate materials, or an alloy thereof.

In this exemplary embodiment, the memory cell 1100 is a 3 CPP memory cell. CPP refers to the distance between adjacent features, such as MD contacts 1220a-1220i and polysilicon lines 1230a-1230l. As can be seen from FIG. 12, the CPP between the cut region portion 1240f and the source/drain contact 1220 e is 1 unit (e.g., 1 nm). Similarly, the CPP between the source/drain contacts 1220 e, 1220 f is 1 unit and the CPP between the source/drain contacts 1220 f, 1220 g is also 1 unit.

From the above description, a cut region portion 1240 is between an adjacent pair of memory cells, decreasing a CPP therebetween. This decrease in CPP results in a relatively smaller device area for the device 100 of the present disclosure. For example, as illustrated in FIG. 12, instead of gate regions and/or MD layers found in, e.g., PODE and CPODE structures, a cut region 1240 is formed between an adjacent pair of memory cells 1100. This minimizes the CPP between an adjacent pair of memory cells of the device 100 from greater than 1 unit (e.g., 5 units) to less than 5 units (e.g., 1 unit). As a result, the device area of the device 100 of the present disclosure can be reduced by up to 20% to 50% compared to PODE and CPODE structures.

FIG. 13 is a flowchart of an exemplary method 1300 of manufacturing a device 100 in accordance with various embodiments of the present disclosure. The example method 1300 will now be described with further reference to FIGS. 1-12 for ease of understanding. It is understood that the method 1300 is applicable to structures other than those of FIGS. 1-12. Further, it is understood that additional operations can be provided before, during, and after the method 1300, and some of the operations described below can be replaced or eliminated, in an alternative embodiment of the method 1300.

In operation 1310, the device manufacturing tool, receives a memory cell layout, e.g., memory cell 300 layout. Subsequently, the device manufacturing tool receives a substrate, which can be made from silicon, germanium, III-V semiconductors, other suitable substrate materials, and their alloys. In operation 1320, the device manufacturing tool forms a diffusion region, e.g., diffusion region 310, over the substrate. Next, the device manufacturing tool fabricates a plurality of transistors, e.g., transistors (T1, T2), over the diffusion region 310 using the memory cell 300 layout received in operation 1310. For example, in operation 1330, the device manufacturing tool forms source and drain regions, e.g., source and drain regions 210-240, over the diffusion region 310. In this exemplary embodiment, operation 1330 includes implanting a dopant in the diffusion region 310. Dopants may include arsenic, phosphorous, boron, gallium, antimony, other suitable source/drain dopants, or combinations thereof.

In operation 1340, the device manufacturing tool lightly dopes channel regions of the transistors (T1, T2) to control their conductivity. In an alternative embodiment, the device manufacturing tool leaves the channel region undoped. In operation 1350, the device manufacturing tool forms gate regions, e.g., gate region 340, 350, over the channel regions, for example, by: applying a thin layer of insulating material, e.g., silicon dioxide, on the channel regions to form a gate dielectric; depositing a conductive material on the gate dielectric; and patterning the conductive material.

In operation 1360, the device manufacturing tool forms a source/drain contact, e.g., MD layers 320, 330, over each source and drain regions 210-240. In operation 1370, the device manufacturing tool etches a trench in a cut region, e.g., cut region 360, of the substrate through the diffusion region 310 using the memory cell 300 layout received in operation 1310. In operation 1380, the device manufacturing tool fills the trench with a dielectric material. As described heretofore, the cut region 360 facilitates the scaling down of the CPP in the device 100, resulting in the reduction of the device area of the device 100 of up to 20% to 50% compared to PODE and CPODE structures.

In an embodiment, a device comprises a plurality of memory cells, each including a diffusion region and a plurality of transistors. The diffusion region is formed over a substrate. Each transistor is fabricated over the diffusion region and includes one or more source/drain contacts and one or more gate regions. The source/drain contacts and the gate regions are arranged along a first direction, each extend in a second direction transverse to the first direction, and overlap the diffusion region in a third direction transverse to the first and second directions. The gate regions of an adjacent pair of memory cells are free of a source/drain contact therebetween and have substantially the same contact poly pitch (CPP) as an adjacent pair of gate regions of a memory cell.

In another embodiment, a device comprises a plurality of memory cells, each including a diffusion region and a plurality of transistors. The diffusion region is formed over a substrate. Each transistor is fabricated over the diffusion region and includes one or more source/drain contacts and one or more gate regions. The source/drain contacts and the gate regions are arranged along a first direction, each extend in a second direction transverse to the first direction, and overlap the diffusion region in a third direction transverse to the first and second directions. The gate regions of an adjacent pair of transistors are free of a source/drain contact therebetween and have substantially the same contact poly pitch (CPP) as an adjacent pair of gate regions of a transistor.

In another embodiment, a method of manufacturing a device comprises receiving a memory cell layout and forming a plurality of memory cells using the memory cell layout. Forming the memory cells includes forming a diffusion region over a substrate and fabricating a plurality of transistors over the diffusion region. Each transistor includes one or more source/drain contacts and one or more gate regions. The source/drain contacts and the gate regions are arranged along a first direction, each extend in a second direction transverse to the first direction, and overlap the diffusion region in a third direction transverse to the first and second directions. Forming the memory cells is such gate regions of an adjacent pair of memory cells have a smaller contact poly pitch (CPP) than a memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a plurality of memory cells, each memory cell including:
a diffusion region formed over a substrate; and
a plurality of transistors fabricated over the diffusion region, wherein:
each transistor includes one or more source/drain contacts and one or more gate regions; and
gate regions of an adjacent pair of memory cells are free of a source/drain contact therebetween and have substantially the same contact poly pitch (CPP) as an adjacent pair of gate regions of a memory cell.

2. The device of claim 1, wherein:
the memory cell is a 2 CPP memory cell;
the plurality of the transistors further include a first source/drain contact connected to a floating source/drain terminal and a second source/drain contact connected to a bit line; and
the first and second source/drain contacts have a CPP of 1 unit.

3. The device of claim 1, wherein:
the memory cell is a 3 CPP memory cell;
the plurality of the transistors include:
a first source/drain contact connected to a floating source/drain terminal;
a second source/drain contact connected to a bit line;
a third source/drain contact between the first and second source/drain contacts;
the first and third source/drain contacts have a CPP of 1 unit; and
the second and third source/drain contacts have a CPP of 1 unit.

4. The device of claim 1, further comprising a cut region between the gate regions of an adjacent pair of memory cells, wherein the cut region includes a trench formed in the substrate and a dielectric layer deposited in the trench.

5. The device of claim 4, wherein the cut region and a source/drain contact connected to a floating source/drain terminal have substantially the same CPP as the adjacent pair of gate regions of a memory cell.

6. The device of claim 4, wherein:
the cut region surrounds an adjacent pair of memory cells; and
the cut region is at left, right, and top boundaries of the memory cells.

7. The device of claim 1, wherein the memory cell further includes:
a first source/drain contact connected to a source/drain region of a first transistor and a source/drain region of a second transistor;
a cut region including a trench formed in the substrate and a dielectric material deposited in the trench;
a first gate region corresponding to a gate terminal of the first transistor and between the first source/drain contact and the cut region;
a second source/drain contact connected to a bit line; and
a second gate region corresponding to a gate terminal of the second transistor and between the first and second source/drain contacts.

8. A device comprising:
a plurality of transistors fabricated over a substrate, wherein:
each transistor includes one or more source/drain contacts and one or more gate regions; and
gate regions of an adjacent pair of transistors are free of a source/drain contact therebetween and have substantially the same contact poly pitch (CPP) as an adjacent pair of gate regions of a transistor.

9. The device of claim 8, further comprising a plurality of memory cells, wherein:
each memory cell includes the plurality of transistors and a first diffusion region formed over the substrate;
the memory cell is a 2 CPP memory cell;
the plurality of the transistors further include a source/drain terminal and first and second source/drain contacts connected to the source/drain terminal; and
the first and second source/drain contacts have a CPP of 1 unit.

10. The device of claim 8, further comprising a plurality of memory cells, wherein:
each memory cell includes the plurality of transistors and a first diffusion region formed over the substrate;
the memory cell is a 3 CPP memory cell;
the plurality of the transistors further include:
a first source/drain contact;
a second source/drain contact connected to a bit line;
a third source/drain contact between the first and second source/drain contacts;
the first and third source/drain contacts have a CPP of 1 unit; and
the second and third source/drain contacts have a CPP of 1 unit.

11. The device of claim 8, further comprising a cut region that surrounds two or more transistors.

12. The device of claim 8, further comprising:
a plurality of memory cells, wherein each memory cell includes the plurality of transistors and a first diffusion region formed over the substrate; and
a cut region that divides the first diffusion region into halves.

13. The device of claim 8, further comprising:
a plurality of memory cells, wherein each memory cell includes the plurality of transistors and a first diffusion region formed over the substrate; and
a first cut region portion that defines a first edge of the first diffusion region;
a second cut region portion that abuts a second edge of the first diffusion region; and
a third cut region portion interconnecting the first and second cut region portions.

14. The device of claim 8, wherein the source/drain contacts and the gate regions are arranged along a first direction each extend in a second direction transverse to the first direction, and overlap the first diffusion region in a third direction transverse to the first and second directions, and the device further comprises:
a plurality of memory cells, wherein each memory cell includes the plurality of transistors and a first diffusion region formed over the substrate;
a second diffusion region formed over the substrate and spaced apart from the first diffusion region in the second direction;
one or more source/drain contacts formed over the second diffusion region;
one or more gate regions formed over the second diffusion region; and
cut region portions surrounding the one or more source/drain contacts and the one or more gate regions.

15. A method of manufacturing a memory device, the method comprising:
forming a diffusion region over a substrate;
fabricating a plurality of transistors over the diffusion region, wherein each transistor includes one or more source/drain contacts and one or more gate regions; and
forming a plurality of memory cells, each including the plurality of transistors, such that gate regions of an adjacent pair of memory cells have a smaller contact poly pitch (CPP) than a memory cell.

16. The method of claim 15, wherein:
the memory cell is a 2 CPP memory cell or greater; and
the gate regions of an adjacent pair of memory cells have a CPP of 1 unit.

17. The method of claim 16, further comprising:
etching a trench in the substrate through the diffusion region; and
filling the trench with a dielectric material to form a first cut region portion between the gate regions of an adjacent pair of memory cells.

18. The method of claim 15, further comprising:
connecting a first source/drain contact to a source/drain region of a first transistor and a source/drain region of a second transistor;
forming a cut region by:
etching a trench in the substrate; and
depositing a dielectric material in the trench;
depositing a gate material to form first gate region that corresponds to a gate terminal of the first transistor and that is between the first source/drain contact and the cut region;
connecting a second source/drain contact to a bit line; and
depositing a gate material to form a second gate region that corresponds to a gate terminal of the second transistor and that is between the first and second source/drain contacts.

19. The method of claim 15, further comprising:
implanting a dopant in the diffusion region to form a floating source/drain region; and
connecting a source/drain contact to the floating source/drain region.

20. The method of claim 15, further comprising:
forming second and third cut region portions that respectively define opposite edges of the diffusion region; and
interconnecting the first, second, and third cut region portions with a fourth cut region portion.
